(19) United States
(12) Patent Application Publication
(10) Pub. No.: US 2026/0006927 A1
(43) Pub. Date: Jan. 1, 2026

(54) Image-sensing array with autofocus pixels and enhanced resolution

(71) Applicant: APPLE INC., Cupertino, CA (US)

(72) Inventors: Xiangli Li, Palo Alto, CA (US); Gilad Michael, Sunnyvale, CA (US); Jiaju Ma, Arcadia, CA (US)

(21) Appl. No.: 19/094,917

(22) Filed: Mar. 30, 2025

Related U.S. Application Data
(60) Provisional application No. 63/665,860, filed on Jun. 28, 2024.

(51) Int. Cl. H10F 39/00; H04N 23/67; H04N 25/13; H04N 25/704; H04N 25/78

(52) U.S. Cl. CPC H10F 39/8053; H04N 23/672; H04N 25/134; H04N 25/704; H04N 25/78; H10F 39/8063

(57) ABSTRACT

An image sensing device includes a semiconductor substrate and a first array of photodetectors disposed on the substrate. Readout circuits, which are disposed on the substrate, are coupled to respective pairs of the photodetectors, and are configured to output signals from the respective pairs in at least a first mode, in which the signals are read out individually from each of the photodetectors, and a second mode, in which the signals are binned together pairwise. A color filter layer includes a matrix of red, green, and blue tiles overlying respective pairs of the photodetectors. A second of array microlenses, overlying the color filter layer, includes first microlenses overlying the respective pairs of the photodetectors that are overlain by the red and blue tiles and second microlenses individually overlying each of the photodetectors in the respective pairs that are overlain by at least some of the green tiles.

### CROSS-REFERENCE TO RELATED APPLICATION

This application claims the benefit of U.S. Provisional Patent Application 63/665,860, filed Jun. 28, 2024, which is incorporated herein by reference.

### FIELD

The present invention relates generally to image sensing arrays and particularly to arrays including autofocus pixels and methods for their fabrication and use.

### BACKGROUND

Camera systems use autofocus (AF) in many applications to ensure that relevant portions of scenes, at varying distances from the camera, are acquired in sharp focus. Some autofocus systems use image information output by the image sensor of the camera in estimating the optimal distance of the image sensor from the camera lens. On-board electromechanical components then drive the lens position to the optimal distance from the image sensor.

To improve autofocus performance, some cameras use dual-pixel autofocus, and particularly phase difference-based autofocus, based on signals output by special pixels in the image sensing array that are divided into two sub-pixels. These special pixels can be created, for example, by fabricating a metal shield over certain pixels in such a way as to obscure one half of the sensing area of each such pixel. Phase-difference autofocus logic compares the outputs of the divided sub-pixels in order to estimate whether the image is in focus, and thus provides feedback in order to drive the lens to converge rapidly to a position at which the image is in focus.

U.S. Pat. No. 11,563,910, whose disclosure is incorporated herein by reference, describes an image capture device including an array of pixels. Each pixel includes a 2×2 array of photodetectors. The image capture device also includes an array of 1×2 on-chip lenses (OCLs) disposed over the array of pixels, in a manner that is said to improve phase detection autofocus (PDAF).

U.S. Patent Application Publication 2023/0090827, whose disclosure is incorporated herein by reference, describes image capture devices that includes an array of pixels, each pixel including a photodetector. A Bayer pattern color filter is disposed over a 4×4 subset of pixels in the array of pixels. The Bayer pattern color filter defines a first 2×2 subset of pixels sensitive to red light; a second 2×2 subset of pixels sensitive to green light; a third 2×2 subset of pixels sensitive to green light; and a fourth 2×2 subset of pixels sensitive to blue light. A set of OCLs is disposed over the pixels, including 1×1, 1×2, and 2×2 OCLs in different embodiments.

In the present description and in the claims, the terms “light” and “optical radiation” are used interchangeably to refer to electromagnetic radiation in any of the visible, infrared, and ultraviolet spectral ranges.

### SUMMARY

Embodiments of the present invention that are described hereinbelow provide improved image sensing arrays and image capture devices.

There is therefore provided, in accordance with an embodiment of the invention, an image sensing device, including a semiconductor substrate and a first array of photodetectors disposed on the substrate. Readout circuits are disposed on the substrate and coupled to respective pairs of the photodetectors, and are configured to output signals from the respective pairs in at least a first mode, in which the signals are read out individually from each of the photodetectors, and a second mode, in which the signals are binned together pairwise. A color filter layer includes a matrix of red, green, and blue tiles overlying respective pairs of the photodetectors. A second array of microlenses overlies the color filter layer, including first microlenses overlying the respective pairs of the photodetectors that are overlain by the red and blue tiles and second microlenses individually overlying each of the photodetectors in the respective pairs that are overlain by at least some of the green tiles.

In some embodiments, the pairs of the photodetectors that are overlain by the first microlenses define phase detection autofocus (PDAF) pixels, and the readout circuits are configured to output a difference between the signals output by the photodetectors in the pairs in the PDAF pixels.

There is also provided, in accordance with an embodiment of the invention, imaging apparatus, including the device as described above and objective optics configured to image a target onto the device. An autofocus mechanism is configured to adjust a focal property of the objective optics. A controller is configured to drive the autofocus mechanism responsively to signals output by the PDAF pixels.

In some embodiments, the controller is further configured to reconstruct a full-color image based on signals output by the photodetectors by first computing a green image by interpolating the signals of the photodetectors that are overlain by the green tiles over regions that are overlain by the red and blue tiles, and then computing red and blue images by interpolating the signals of the photodetectors that are overlain by the red and blue tiles using the green image.

In a disclosed embodiment, the photodetectors have an aspect ratio of 1×2 and are arranged such that the pairs of the photodetectors are square in area.

Additionally or alternatively, some of the pairs of the photodetectors are disposed along respective rows of the first array, while others of the pairs of the photodetectors are disposed along respective columns of the first array.

In some embodiments, each of the red, green, and blue tiles covers a single respective pair of the photodetectors. Alternatively, each of the red, green, and blue tiles covers a respective group of four pairs of the photodetectors.

In a disclosed embodiment, the color filter layer further includes additional filters over some of the photodetectors of a color other than red, green, or blue.

There is additionally provided, in accordance with an embodiment of the invention, a method for image sensing, which includes providing a semiconductor substrate including a first array of photodetectors and readout circuits, which are coupled to respective pairs of the photodetectors, and which are configured to output signals from the respective pairs in at least a first mode, in which the signals are read out individually from each of the photodetectors, and a second mode, in which the signals are binned together pairwise. A color filter layer is overlaid on the first array and includes a matrix of red, green, and blue tiles overlying respective pairs of the photodetectors. A second array of microlenses is overlaid on the color filter layer and includes first microlenses overlying the respective pairs of the photodetectors that are overlain by the red and blue tiles and second microlenses individually overlying each of the photodetectors in the respective pairs that are overlain by at least some of the green tiles.

### BRIEF DESCRIPTION OF THE DRAWINGS

The present invention will be more fully understood from the following detailed description of the embodiments thereof, taken together with the drawings in which:

FIG. 1 is a schematic side view of a camera comprising an image sensing device with sparse autofocus pixels, in accordance with an embodiment of the invention;

FIGS. 2, 3A, 3B, 4A, 4B, 4C, 5, 6 and 7 are schematic partial frontal views of image sensing devices, in accordance with embodiments of the invention; and

FIG. 8 is a flow chart that schematically illustrates a method for processing a mosaic image output by an image sensing device, in accordance with an embodiment of the invention.

### DETAILED DESCRIPTION

### Overview

Traditional Bayer-type color image sensors comprise an array of photodetectors overlaid with a color filter layer comprising a matrix of red, green, and blue tiles with the same pitch as the photodetector array, i.e., each color tile in the matrix covers a single photodetector. (The term “tile” is used in the present description and in the claims to refer to a contiguous region of a single color within the color filter layer, while a pattern of interleaved tiles or other elements of different colors is referred to as a “mosaic.”) For improved resolution and low-light performance (by binning together the signals from adjacent detectors), in some image sensors each colored tile in the color filter layer overlies a group of two or more photodetectors. This type of arrangement is described, for example, in the above-mentioned U.S. Pat. No. 11,563,910 and U.S. Patent Application Publication 2023/0090827.

Some image sensing devices of this sort include readout circuits, which are coupled to respective pairs or larger groups of adjacent photodetectors. In full-resolution mode, the readout circuits read out signals individually from each of the photodetectors. When higher sensitivity is desired, the readout circuits bin together the signals from pairs or groups larger of the photodetectors. For purposes of phase detection autofocus (PDAF), the readout circuits may output a difference between the signals generated by adjacent photodetectors in PDAF groups.

At the output from the camera, the mosaic of red, green, and blue raw color pixels is interpolated to reconstruct a full-color (RGB) image, with red, green, and blue intensity values for each pixel. Typically, the spatial resolution of the RGB image depends mainly on the resolution of the green color channel. When PDAF pixels are included in the green regions of the image sensor, as in U.S. Pat. No. 11,563,910, they can degrade the resolution in these regions, since the on-chip lenses (OCLs) introduce a small amount of local blur.

Embodiments of the present invention that are described herein remedy this problem by incorporating PDAF pixels only in the red and/or blue regions of the photodetector array. In these embodiments, the photodetectors are arranged in pairs, with readout circuits coupled to respective pairs of the photodetectors. A color filter layer over the photodetector array comprises a matrix of red, green, and blue tiles, which overlie respective pairs of the photodetectors. A microlens array, such as an array of OCLs, overlying the color filter layer, comprises shared microlenses overlying the pairs of photodetectors that are overlain by the red and blue tiles, while individual microlenses overlie each of the photodetectors in the pairs that are overlain by at least some of the green tiles.

The pairs of photodetectors with the shared microlenses define PDAF pixels, whose output signals can be used in focusing the camera in which the image sensing device is installed. All the microlenses in the red and blue regions of the color filter layer may be of this type, or alternatively, some of the photodetectors in the red and/or blue regions may have individual microlenses for enhanced resolution. The outputs of the photodetectors of each of the colors can be binned together when enhanced sensitivity is required. In good lighting conditions, however, the individual microlenses over the photodetectors in the green regions provide enhanced spatial resolution. Limiting the distribution of PDAF pixels to certain areas of the photodetector array, such as to the red and blue regions, is referred to herein as a sparse distribution of the PDAF pixels.

Although the embodiments described herein are based specifically, for the sake of clarity and concreteness, on color matrices of red, green, and blue tiles, overlying respective pairs or groups of four pairs of photodetectors, the principles of the present invention may be applied to color filter layers including other colors, as well as to devices that provide larger or smaller numbers of photodetectors in each color region. As another example, the color filter arrays in the embodiments described below may be modified to include clear (white) or gray regions. All such alternative implementations are considered to be within the scope of the present invention.

### System Description

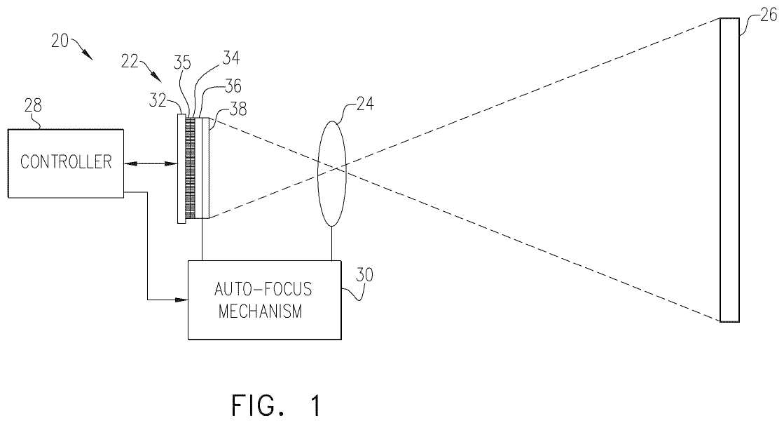

FIG. 1 is a schematic side view of a camera 20 comprising an image sensing device 22 with a novel mosaic filter layout, in accordance with an embodiment of the invention. Objective optics 24 image a target 26 onto image sensing device 22. An autofocus mechanism 30 adjusts a focal property of the objective optics 24, for example by shifting the distance between optics 24 and device 22 or by adjusting the focal length of optics 24, as is known in the art. A controller 28 processes the signals output by PDAF pixels in image sensing device 22 and drives autofocus mechanism 30 in response to these signals so as to form a well-focused image on the image sensing device.

Image sensing device 22 comprises a semiconductor substrate 32, such as a silicon wafer substrate. An array of photodetectors such as silicon photodiodes, is formed on substrate 32 at a predefined pitch, along with suitable switching and readout circuits 35. The photodetectors and associated circuits may be formed using any suitable process of thin film deposition and photolithography, such as a complementary metal-oxide-semiconductor (CMOS) process. The circuits described in the above-mentioned U.S. Pat. No. 11,563,910, for example, may be adapted for this purpose. A color filter layer 36 is deposited over photodetectors 34, and an array of microlenses 38 is disposed over color filter layer 36. Typically (although not necessarily), microlenses 38 comprise OCLs, which are also formed by a process of material deposition, photolithography, and etching, as is known in the art.

The figures that follow show various configurations of color filter layer 36 and microlenses 38 that may be used in accordance with embodiments of the invention. These figures show only partial views of the color filter matrix and corresponding microlenses, since the entire image sensing device, typically comprising many megapixels, cannot practically be shown in patent drawings.

### Image Sensor Configurations

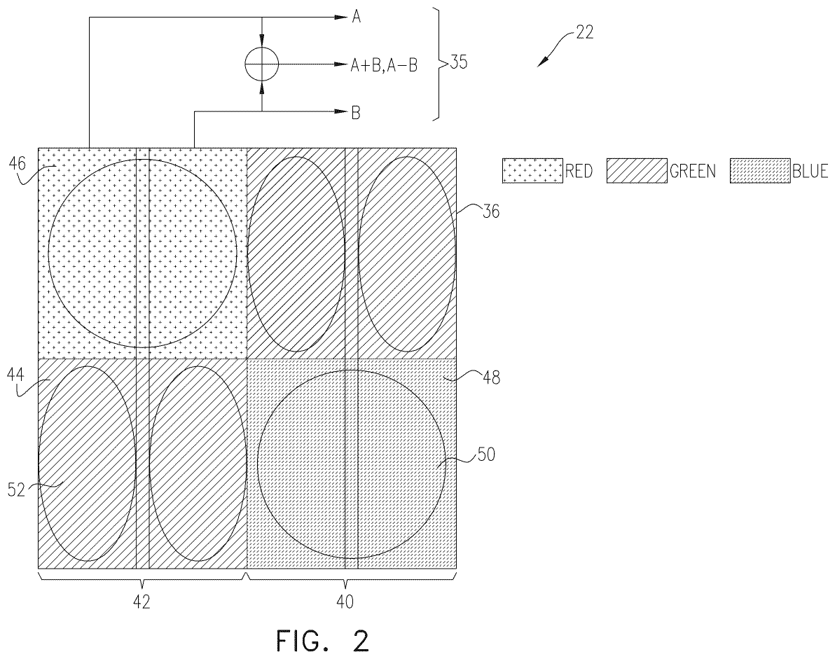

FIG. 2 is a schematic partial frontal view of image sensing device 22, in accordance with an embodiment of the invention. Readout circuits 35 are coupled to respective pairs 40, 42 of photodetectors 34, and are capable of outputting signals from the respective pairs either in an individual mode, in which the signals (A, B) are read out individually from each of the photodetectors, or in a combined mode, in which the signals are binned together pairwise to give sum (A+B) and/or difference (A−B) signals. The summed signals are used to enhance sensitivity in low-light conditions, while the difference signals can be used for PDAF, to be applied by controller 28 in estimating whether the image is in focus, and thus to drive autofocus mechanism 30 to a position at which the image is in focus. The sets of pairs 40 and 42 of the photodetectors are interleaved in a grid pattern.

Color filter layer 36 comprises a matrix of green tiles 44, red tiles 46, and blue tiles 48, each tile overlying a respective pair of photodetectors 34. Pairs 40 of the photodetectors are overlain by respective red tiles 46 or blue tiles 48, while pairs 42 are overlain by green tiles 44. Each of pairs 40 is overlain by a common microlens 50, to enable binning and PDAF functions in the red and blue pixels. On the other hand, within pairs 42, each photodetector is overlain by its own individual microlens 52 for enhanced resolution in the green pixels.

The embodiment of FIG. 2, as well as the embodiments shown in the figures that follow, is referred to as a “split pixel” image sensor design, since each pair of photodetectors make up a single image pixel for purposes of binning and PDAF. The pitch of these split pixels is equal to the distance between the gridlines in the figures. In FIG. 2, the mosaic of tiles 44, 46, 48 has the same pitch as the pixels. In the pictured embodiments, the pixels defined by the photodetector pairs are square in area, and each individual photodetector thus has a 1×2 aspect ratio, as illustrated in the figures. Common microlenses 50 are round and are referred to as “1×1 OCLs”; while individual microlenses 52 are oval and are referred to as “1×0.5 OCLs.” The pairs of the photodetectors may be disposed along respective rows of the photodetector array, with a vertical split between the photodetectors in each pair, as shown in FIG. 2. Alternatively, the photodetector pairs may be disposed along respective columns, or they be mixed, with some pairs disposed along rows and others along columns.

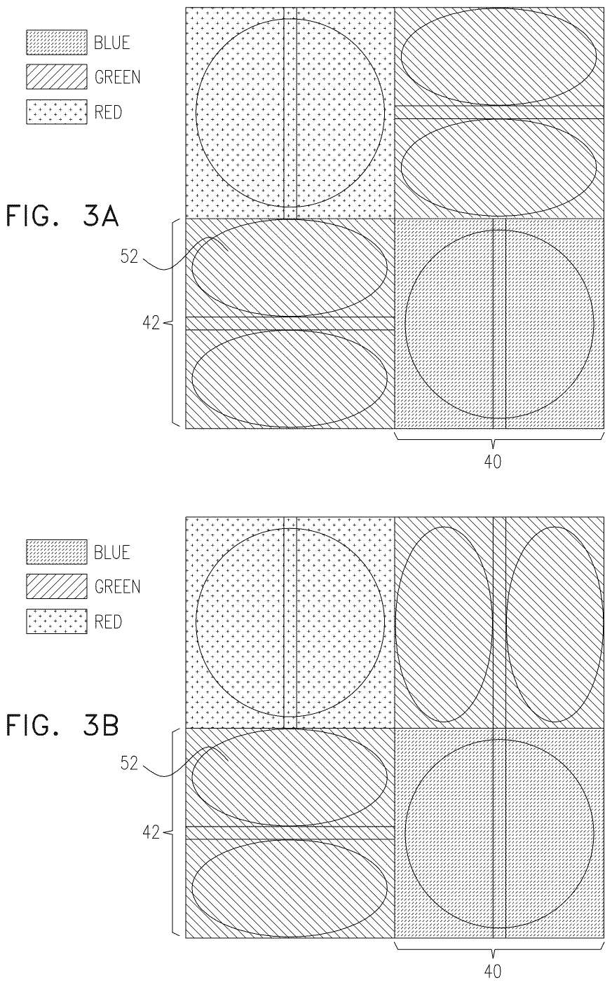

FIGS. 3A and 3B are schematic partial frontal view of image sensing devices 22, in accordance with other embodiments of the invention. These embodiments are similar to the embodiment of FIG. 2, and the description and numbering of repeated features in this and subsequent embodiments have been omitted for the sake of brevity. In the present embodiments, however, pairs 42 of the photodetectors that are overlain by green tiles 44 are oriented differently: Either all of pairs 42 are disposed along the columns of the photodetector array as shown in FIG. 3A; or some of pairs 42 are disposed along respective rows, while others are disposed along respective columns as shown in FIG. 3B. Individual microlenses 52 are oriented accordingly. These configurations are useful in improving the resolution of device 22 in the vertical direction.

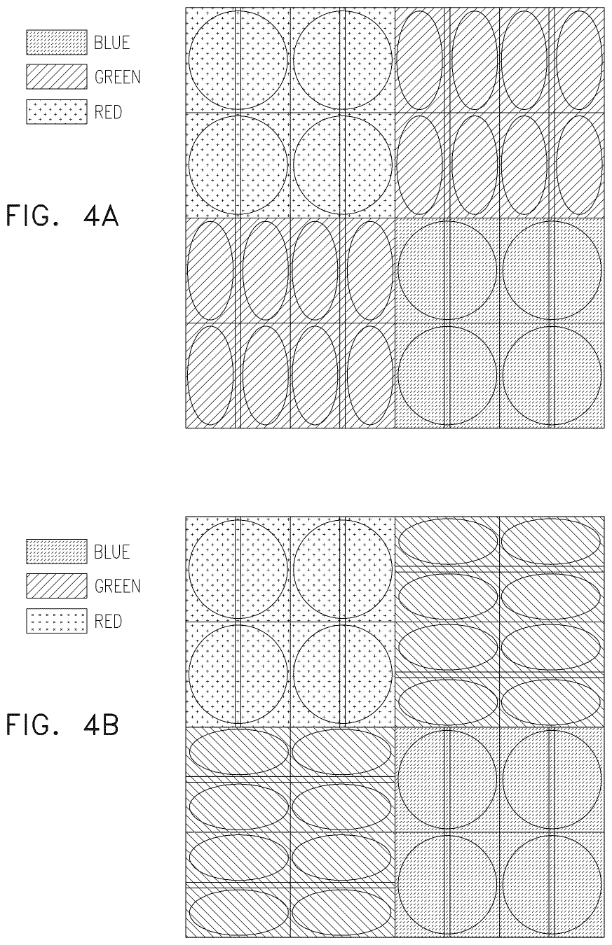

FIGS. 4A, 4B, and 4C are schematic partial frontal view of image sensing devices 22, showing other possible distributions of 1×2 microlenses, in accordance with alternative embodiments of the invention. In these embodiments, each of the red, green, and blue tiles covers a respective group of four pairs of the photodetectors. The pairs of photodetectors that are overlain by green tiles may be disposed along respective rows (FIG. 4A) or columns (FIG. 4B) of the array. Alternatively, some pairs of photodetectors may be disposed along respective rows, while others are disposed along respective columns (FIG. 4C). The microlenses overlying the green photodetectors are oriented accordingly.

The sorts of embodiments that are shown in FIGS. 4A-4C are useful in enabling binning of signals not only between pairs of photodetectors as in the preceding embodiments, but also among larger groups of adjacent photodetectors that are covered by the same color tile. Thus, these embodiments can achieve better signal/noise performance under low-light conditions while still providing high resolution in good lighting conditions, as well as enabling PDAF control in all binning modes. The pictured examples enable binning of signals from eight adjacent photodetectors. In alternative embodiments, each color tile may cover even larger group of photodetectors, for example a group of sixteen pairs of photodetectors.

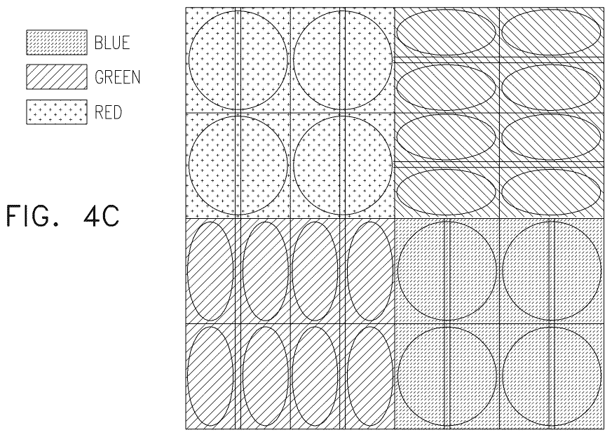

FIG. 5 is a schematic partial frontal view of image sensing device 22, in accordance with yet another embodiment of the invention. This embodiment is similar to the embodiment of FIG. 4C, except that in FIG. 5, each green tile overlies two pairs of photodetectors that are disposed along respective rows of the array and two pairs that are disposed along respective columns, with microlenses oriented accordingly. This arrangement may achieve better resolution under good lighting conditions than the preceding embodiments.

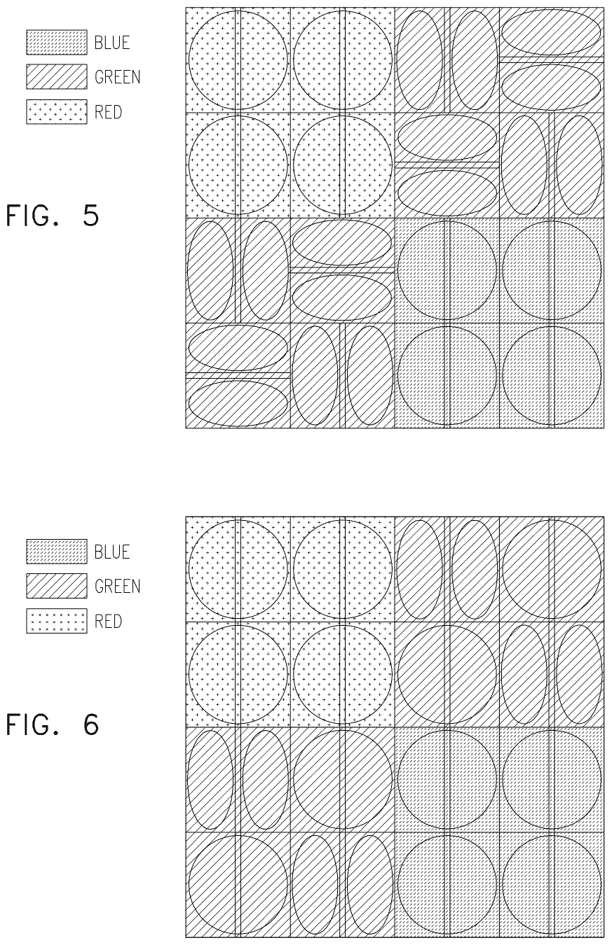

FIG. 6 is a schematic partial frontal view of image sensing device 22, in accordance with an alternative embodiment of the invention. This embodiment is similar to the embodiment of FIG. 4A, except that in FIG. 6, some of the pairs of photodetectors that are overlain by the green tiles are overlain by shared microlenses (1×1 OCLs). The other photodetectors under the green tiles are overlain by individual microlenses (1×0.5 OCLs). This arrangement can improve autofocus performance, at the possible expense of slightly reduced resolution.

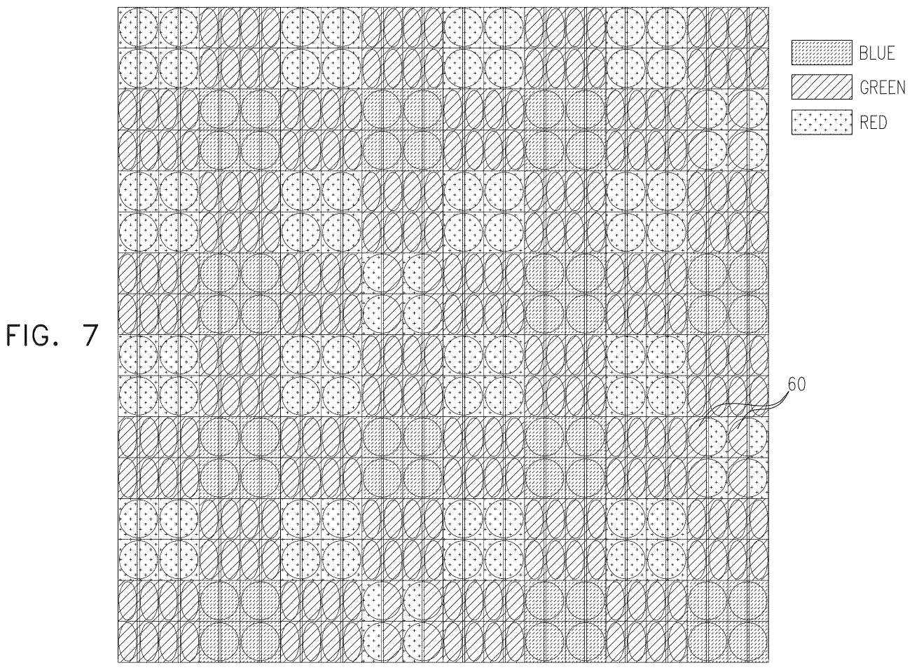

FIG. 7 is a schematic partial frontal view of image sensing device 22, showing still further possible configurations of color filters and microlenses in accordance with an alternative embodiment of the invention. In this embodiment, within some of the regions containing red tiles, the color filter layer also comprises filters 60 of a color other than red overlying some of the photodetectors that are located under the 1×1 OCLs. Alternatively or additionally, the blue regions may include filters of a different color.

Filters 60 may be of a variety of different colors, depending on application requirements. For example, filters 60 may be green, to improve the resolution of the green color channel. Alternatively, filters 60 may be clear or grey (neutral density) to improve both the resolution and the spectral sensing range of the device. A metal shield or grid may be formed over the red or blue photodetectors in these groups to provide PDAF information. This sort of shield or grid is useful particularly in preserving PDAF information when the outputs of groups of photodetectors in the array of FIG. 7 are summed together.

### Processing Method

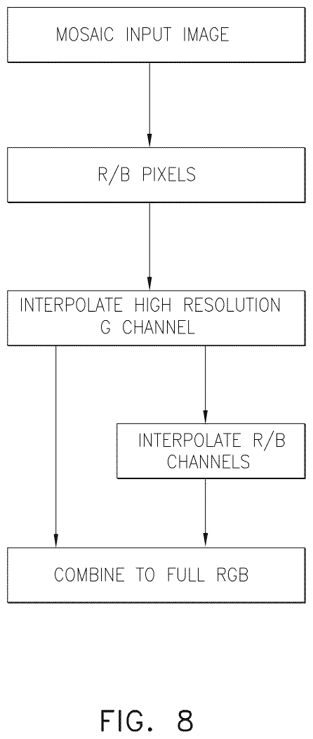

FIG. 8 is a flow chart that schematically illustrates a method for processing a mosaic image output by image sensing device 22, in accordance with an embodiment of the invention. Controller 28 (FIG. 1) applies this method in reconstructing a full-color RGB image based on signals output by pairs of photodetectors 34 that are overlaid by the red, green, and blue tiles shown in the preceding figures, which are captured as a mosaic input image.

In the red and blue regions, at least some of the photodetectors share common microlenses for purposes of autofocus. Controller 28 sums the signals output by each such group of two or four photodetectors to compute an extended pixel value. Controller 28 computes a high-resolution green image by interpolating the signals received from the photodetectors in the green regions over the red and blue regions. The controller then computes red and blue images by interpolating the pixel values of the photodetectors in the red and blue regions (including the summed autofocus groups), using the green image to furnish missing detail. The controller then combines the resulting red and blue images with the green image to provide the full RGB output.

In an alternative embodiment, a neural network may be trained to convert the raw mosaic input to a full RGB output, without explicitly performing the interpolation steps described above.

Although the embodiments described above include particular types and distributions of microlenses over a color image sensing device, the principles these embodiments may be applied in creating other microlens patterns, in accordance with the principles of the present invention. It will thus be understood that the embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An image sensing device, comprising:
a semiconductor substrate;
a first array of photodetectors disposed on the substrate;
readout circuits, which are disposed on the substrate and coupled to respective pairs of the photodetectors, and which are configured to output signals from the respective pairs in at least a first mode, in which the signals are read out individually from each of the photodetectors, and a second mode, in which the signals are binned together pairwise;
a color filter layer comprising a matrix of red, green, and blue tiles overlying respective pairs of the photodetectors; and
a second array of microlenses overlying the color filter layer, including first microlenses overlying the respective pairs of the photodetectors that are overlain by the red and blue tiles and second microlenses individually overlying each of the photodetectors in the respective pairs that are overlain by at least some of the green tiles.

2. The device according to claim 1, wherein the pairs of the photodetectors that are overlain by the first microlenses define phase detection autofocus (PDAF) pixels, and wherein the readout circuits are configured to output a difference between the signals output by the photodetectors in the pairs in the PDAF pixels.

3. Imaging apparatus, comprising:
the device according to claim 2;
objective optics configured to image a target onto the device;
an autofocus mechanism configured to adjust a focal property of the objective optics; and
a controller configured to drive the autofocus mechanism responsively to signals output by the PDAF pixels.

4. The apparatus according to claim 3, wherein the controller is further configured to reconstruct a full-color image based on signals output by the photodetectors by first computing a green image by interpolating the signals of the photodetectors that are overlain by the green tiles over regions that are overlain by the red and blue tiles, and then computing red and blue images by interpolating the signals of the photodetectors that are overlain by the red and blue tiles using the green image.

5. The device according to claim 1, wherein the photodetectors have an aspect ratio of 1×2 and are arranged such that the pairs of the photodetectors are square in area.

6. The device according to claim 1, wherein some of the pairs of the photodetectors are disposed along respective rows of the first array, while others of the pairs of the photodetectors are disposed along respective columns of the first array.

7. The device according to claim 1, wherein each of the red, green, and blue tiles covers a single respective pair of the photodetectors.

8. The device according to claim 1, wherein each of the red, green, and blue tiles covers a respective group of four pairs of the photodetectors.

9. The device according to claim 1, wherein the color filter layer further comprises additional filters over some of the photodetectors of a color other than red, green, or blue.

10. A method for image sensing, comprising:
providing a semiconductor substrate including a first array of photodetectors and readout circuits, which are coupled to respective pairs of the photodetectors, and which are configured to output signals from the respective pairs in at least a first mode, in which the signals are read out individually from each of the photodetectors, and a second mode, in which the signals are binned together pairwise;
overlaying on the first array a color filter layer comprising a matrix of red, green, and blue tiles overlying respective pairs of the photodetectors; and
overlaying on the color filter layer a second array of microlenses, including first microlenses overlying the respective pairs of the photodetectors that are overlain by the red and blue tiles and second microlenses individually overlying each of the photodetectors in the respective pairs that are overlain by at least some of the green tiles.

11. The method according to claim 10, wherein the pairs of the photodetectors that are overlain by the first microlenses define phase detection autofocus (PDAF) pixels, and wherein the readout circuits are configured to output a difference between the signals output by the photodetectors in the pairs in the PDAF pixels.

12. The method according to claim 11, and comprising imaging a target onto the first array using objective optics, and driving an autofocus mechanism to adjust a focal property of the objective optics responsively to signals output by the PDAF pixels.

13. The method according to claim 12, and comprising reconstructing a full-color image based on signals output by the photodetectors by first computing a green image by interpolating the signals of the photodetectors that are overlain by the green tiles over regions that are overlain by the red and blue tiles, and then computing red and blue images by interpolating the signals of the photodetectors that are overlain by the red and blue tiles using the green image.

14. The method according to claim 10, wherein the photodetectors have an aspect ratio of 1×2 and are arranged such that the pairs of the photodetectors are square in area.

15. The method according to claim 10, wherein some of the pairs of the photodetectors are disposed along respective rows of the first array, while others of the pairs of the photodetectors are disposed along respective columns of the first array.

16. The method according to claim 10, wherein each of the red, green, and blue tiles covers a single respective pair of the photodetectors.

17. The method according to claim 10, wherein each of the red, green, and blue tiles covers a respective group of four pairs of the photodetectors.

18. The method according to claim 10, wherein the color filter layer further comprises additional filters over some of the photodetectors of a color other than red, green, or blue.
